(19) United States
(12) Patent Application Publication
(10) Pub. No.: US 2020/0122197 A1
(43) Pub. Date: Apr. 23, 2020

(54) PIEZOELECTRIC ELEMENT, METHOD OF MANUFACTURING PIEZOELECTRIC ELEMENT, AND ELECTRONIC DEVICE INCLUDING PIEZOELECTRIC ELEMENT

(71) Applicant: POINT ENGINEERING CO., LTD., Asan (KR)

(72) Inventors: Bum Mo AHN, Suwon (KR); Seung Ho PARK, Hwaseong (KR)

(21) Appl. No.: 16/659,098

(22) Filed: Oct. 21, 2019

(30) Foreign Application Priority Data
Oct. 22, 2018 (KR) 10-2018-0125812

(51) Int. Cl. B06B 1/06; H01L 41/18; H01L 41/37

(52) U.S. Cl. CPC B06B 1/0674; G06K 9/0002; H01L 41/37; H01L 41/183

(57) ABSTRACT

Disclosed is a method of manufacturing a piezoelectric pillar enabling highly accurate recognition of a three-dimensional shape and having improved durability while preventing thermal deformation of a mold. The method includes charging a piezoelectric material into at least one filling hole formed in a mold and sintering the piezoelectric material by heating only the piezoelectric material provided in the filling hole to a sintering temperature of the piezoelectric material. Further disclosed and an electronic device including the piezoelectric pillar and a method of manufacturing the electronic device.

### CROSS REFERENCE TO RELATED APPLICATION

The present application claims priority to Korean Patent Application No. 10-2018-0125812, filed Oct. 22, 2018, the entire contents of which is incorporated herein for all purposes by this reference.

### BACKGROUND OF THE INVENTION

### Field of the Invention

The present invention relates to a piezoelectric element, a method of manufacturing a piezoelectric element, and an electronic device including a piezoelectric element.

### Description of the Related Art

An electronic device including a piezoelectric element is a shape measuring device for measuring the shape of a three-dimensional object. The device measures the three-dimensional shape using a method in which a voltage is applied across two electrodes respectively provided on the upper and lower surfaces of a piezoelectric pillar made of a piezoelectric material so that the piezoelectric pillar vertically vibrates to generate a signal, the signal travels to and reflects from the surface of a three-dimensional object and returns toward the piezoelectric pillar, the piezoelectric pillar is deformed by the returned signal, resulting in a potential change, and the shape of the three-dimensional object is measured on the basis of the potential change. In the electronic device, each of the piezoelectric pillars functions as a pixel of an image of a three-dimensional shape.

In biometrics, since a living body has a lower acoustic impedance than a piezoelectric material, sensitivity characteristics are degraded due to impedance mismatching. In order to secure a low acoustic impedance while maintaining excellent piezoelectric properties of a piezoelectric material, a composite piezoelectric structure has been proposed in which a synthetic resin, a high molecular material (polymer), an epoxy, or the like having a low acoustic impedance is formed around a piezoelectric material.

A composite piezoelectric structure can be manufactured, for example, by dicing a piezoelectric ceramic bulk to form dicing grooves in the form of a grid using a precision dicing saw, filling the dicing grooves with an epoxy resin or the like, and curing the epoxy resin. In this case, since the dicing is linearly performed, it is difficult to freely adjust the shape, arrangement, density, and the like of piezoelectric pillars, and there is a design constraint in making a composite piezoelectric structure. In addition, there is a problem in that the dicing takes a long time and chipping of piezoelectric pillars or dicing saw breakage occurs during the dicing process.

On the other hand, a method of using a mold has been proposed to improve flexibility in designing piezoelectric pillars. In this method, a resin mold is first manufactured, and then grooves to be filled with a piezoelectric material are formed through a lithography process. After filling the grooves with a piezoelectric material, the resin mold is removed, and the piezoelectric material is sintered to form the piezoelectric pillars. After that, gaps between each of the piezoelectric pillars are filled again with a low acoustic impedance synthetic resin, a polymer, or an epoxy to manufacture the composite piezoelectric structure.

However, this conventional technique has a problem of requiring a process of forming grooves to be filled with a piezoelectric material on a resin mold, a process of removing the resin mold that is used to fill the grooves with the piezoelectric material, a complicated process of replacing a material around the piezoelectric pillars with a low acoustic impedance material.

Furthermore, since the resin mold must be removed before the piezoelectric material is sintered, there is a problem that the pillars of the piezoelectric material are inclined during the sintering.

On the other hand, a technique of using a silicon mold having a plurality of holes, which is formed by etching a silicon substrate using a reactive ion etching process, as a template has been proposed. This technique includes the steps of filling the holes with a piezoelectric material, sintering the piezoelectric material under high temperature and pressure conditions, removing the silicon mold to produce piezoelectric pillars, and charging a resin into gaps between the piezoelectric pillars, thereby manufacturing a composite piezoelectric structure

However, this conventional technique has a problem that the piezoelectric material and silicon react each other during the sintering of the piezoelectric material. In order to suppress such a reaction, a protective film is formed inside the holes. However, this protective film poses problems in that it increases the manufacturing cost and cannot sufficiently suppress the reaction between the piezoelectric material and the silicon due to the high diffusivity of silicon.

Documents of Related Art

(Patent Document 1) Korean Patent No. 10-1288178

(Patent Document 2) Japanese Patent Publication No. 1996-012181

### SUMMARY OF THE

Accordingly, the present invention has been made keeping in mind the above problems occurring in the related art, and an objective of the present invention is to provide a piezoelectric element being capable of preventing thermal deformation of a mold, enabling high recognition accuracy for a three-dimensional shape, and having improved durability. Another objective of the present invention is to provide a method of manufacturing a piezoelectric element. A further objective of the present invention is to provide an electronic device including a piezoelectric element.

In order to accomplish the objectives of the present invention, according to one aspect of the present invention, there is provided a method of manufacturing a piezoelectric element, the method including: filling a filling hole formed in a mold with a piezoelectric material; and selectively sintering the piezoelectric material by heating only the piezoelectric material provided in the filling hole to a sintering temperature.

In the sintering, the mold may not be heated to the sintering temperature, and only the piezoelectric material may be heated to the sintering temperature to be sintered.

In the sintering, only the piezoelectric material may be heated to the sintering temperature through a rapid thermal process.

In the sintering, only the piezoelectric material may be heated to the sintering temperature through a high frequency heating process.

In the sintering, only the piezoelectric material may be heated to the sintering temperature through a laser heating process.

The sintering may be performed through a rapid thermal process such that the density of an end portion of the sintered piezoelectric material provided in the filling hole is higher than the density of a middle portion of the sintered piezoelectric material.

According to another aspect of the present invention, there is provided a method of manufacturing a piezoelectric element, the method including: preparing an anodic oxide film; forming at least one filling hole perpendicularly extending through the anodic oxide film from an upper surface to a lower surface of the anodic oxide film, separately from a plurality of pores that are naturally formed in the anodic oxide film during the preparing of the anodic oxide film; and forming at least one piezoelectric pillar by filling the at least one filling hole with a piezoelectric material. The forming of the piezoelectric pillar may include a step of selectively heating only the piezoelectric material provided in the filling hole to a sintering temperature of the piezoelectric material.

According to a further aspect of the present invention, there is provided a piezoelectric element including an anodic oxide film and a piezoelectric pillar formed in the anodic oxide film and made of a piezoelectric material that is heated to a sintering temperature to be sintered.

According to a further aspect of the present invention, there is provided an electronic device including a piezoelectric element, the electronic device including: an anodic oxide film; at least one piezoelectric pillar formed in the anodic oxide film and made of a piezoelectric material that is heated to a sintering temperature to be sintered; a first electrode formed on an upper surface of the anodic oxide film; and a second electrode formed on a lower surface of the anodic oxide film.

As described above, the piezoelectric element, the method of manufacturing a piezoelectric element, and the electronic device including a piezoelectric element, according to the present invention, can prevent the thermal deformation of a mold during the sintering of the piezoelectric material so that the mold used as a sintering framework of the piezoelectric material needs not be removed and can be used as it is.

In addition, since ultrasonic waves generated from the side surfaces of the adjacent piezoelectric pillars are effectively attenuated by air pillars formed in the pores of the anodic oxide film, the sensitivity of an ultrasonic biometric sensor to which the piezoelectric element is included can be improved.

### BRIEF DESCRIPTION OF THE DRAWINGS

The above and other objects, features and other advantages of the present invention will be more clearly understood from the following detailed description when taken in conjunction with the accompanying drawings, in which:

FIGS. 1A to 1D are diagrams illustrating a method of manufacturing a piezoelectric pillar according to a preferred embodiment of the present invention;

FIGS. 2 to 6 are diagrams illustrate a method of manufacturing an electronic device including a piezoelectric element according to a preferred embodiment of the present invention;

FIG. 7 is a schematic diagram illustrating the construction of an electronic device including a piezoelectric element according to a preferred embodiment of the present invention;

FIGS. 8 to 12 are diagrams illustrating a process of heating only a piezoelectric material to a sintering temperature, according to a preferred embodiment of the present invention;

FIG. 13 is a diagram illustrating a state in which an electronic device including a piezoelectric element is mounted on a control chip, according to a preferred embodiment of the present invention;

FIG. 14 is a diagram illustrating a state in which an electronic device including a piezoelectric element, according to a preferred embodiment of the present invention, transmits sound waves;

FIG. 15 is a diagram illustrating a state in which an electronic device including a piezoelectric element, according to a preferred embodiment of the present invention, receives sound waves; and

FIG. 16 is a diagram illustrating a state in which an electronic device including a piezoelectric element, according to a preferred embodiment of the present invention, recognizes a fingerprint.

### DETAILED DESCRIPTION OF THE DISCLOSURE

Hereinbelow, exemplary embodiments of the present invention will be described in detail with reference to the accompanying drawings. Throughout the drawings, the same reference numerals will refer to the same or like parts.

The following merely illustrates the principles of the present invention. Therefore, those skilled in the art will be able to implement the principles of the invention and invent various apparatuses that fall within the concept and scope of the invention, although not explicitly described or illustrated herein. In addition, all conditional terms and embodiments herein are described, in principle, for the purpose of aiding understanding of the concept of the present invention and it should be understood that the scope of the present invention is limited to specific embodiments or states described herein.

The above objects, features, and advantages will become more apparent from the following detailed description taken in conjunction with the accompanying drawings, whereby the technical spirit of the invention may be easily implemented by those skilled in the art to which the invention pertains.

Hereinafter, a piezoelectric element, a method of manufacturing a piezoelectric element, and an electronic device including a piezoelectric element according to a preferred embodiment of the present invention will be described in detail with reference to the accompanying drawings.

A method of manufacturing a piezoelectric element according to a preferred embodiment of the present invention includes a process of manufacturing a mold 10 having at least one filling hole 150, a process of filling the at least one filling hole 150 formed in the mold 10 with a piezoelectric material 20, and heating only the piezoelectric material 20 provided in the at least one filling hole 150 to the sintering temperature of the piezoelectric material 20 so that the piezoelectric material 20 will be sintered.

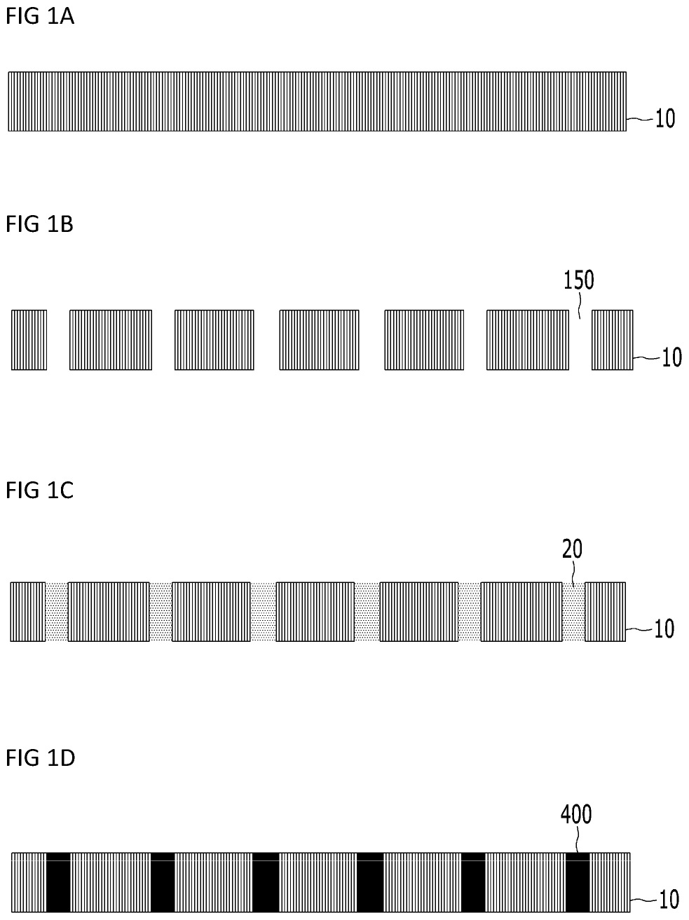

First, as illustrated in FIGS. 1A and 1B, the mold 10 is prepared and the filling hole 150 is formed in the mold 10. The filling hole 150 perpendicularly extends through the mold 10 from the upper surface to the lower surface of the mold 10, but the form of the filling hole 150 is not limited thereto. However, with the configuration in which the filling hole 150 perpendicularly extends through the mold 10 from the upper surface to the lower surface, the piezoelectric material 20 can be relatively easily charged into the filling hole 150 as compared with other cases. In addition, a vacuum pump that sucks air is installed on one side of the mold 10 to generate a negative pressure in the filling hole 150. Due to the negative pressure in the filling hole 150, the piezoelectric material can easily flow into the filling hole 150. With this configuration, the filling hole 150 can be perfectly filled with the piezoelectric material 20. Thus, piezoelectric pillars 400 having a uniform size and improved durability can be formed.

Next, as illustrated in FIG. 1C, the piezoelectric material 20 is charged into the filling holes 150 such that the filling hole 150 can be perfectly filled with the piezoelectric material 20. The piezoelectric material 20 is a piezoelectric ceramic. For example, it may be a PZT-based material such as solid solution of lead zinc titanate (Pb(Zr,Ti)O₃) or lead zinc niobate (Pb(Zn,Nb)O₃) and lead titanate (PbTiO₃) or a solid solution of lead magnesium niobate (Pb(Mg, Nb)O₃) and lead titanate (PbTiO₃). However, the piezoelectric material used in the present invention is not limited thereto. An arbitrary piezoelectric material selected from among various piezoelectric materials can be used according to the embodiments of the present invention. For example, the piezoelectric material 20 may be a single crystal material, a polycrystalline material, a polymer, a thin film, or a composite material composed of a polycrystalline material and a polymer material. Examples of the single crystal material include α-AlPO₄, α-SiO₂, LiTiO₃, LiNbO₃, SrₓBa_{y}Nb₂O₃, Pb₅—Ge₃O₁₁, Tb₂ (MnO₄)₃, Li₂B₄O₇, CdS, ZnO, Bi₁₂SiO₂₀, and Bi₁₂GeO₂₀. Examples of the polycrystalline material include lead zirconate titanate (PZT) series, PT series, PZT-complex perovskite series, and BaTiO₃. Examples of the polymer include PVDF, P(VDF-TrFe), P (VDFTeFE), and TGS. Examples of the thin film include ZnO, CdS, and AlN. Examples of the composite material include PZT-PVDF, PZT-silicon rubber, PZT-epoxy, PZT-foaming polymer, and PZT-foaming urethane.

The piezoelectric material 20 is in the powder form. The powder is charged into the filling holes. When the powder particles of the piezoelectric material 20 are larger than the upper limit of a predetermined size range, the porosity is excessively high, resulting in a high shrinkage rate. Conversely, when the powder particles are smaller than the lower limit, the filling efficiency is excessively low. Therefore, the powder particles having sizes that do not fall within the predetermined range are not desirable. According to a preferred embodiment of the present invention, the size of the powder particles of the piezoelectric material 20 preferably ranges from several tens of nm to 5 μm. More preferably, the power particles are not larger than 1 μm.

The piezoelectric material 20 may be a powder mixture in which particles having different sizes are mixed. Since the particles of the piezoelectric material 20 have different sizes, the porosity of the piezoelectric material charged into the filling holes 150 is reduced. This minimizes shrinkage during sintering of the piezoelectric material 20.

When the process of filling the filling holes 150 formed in the mold 10 with the piezoelectric material 20 is completed, the piezoelectric material 20 is heated to the sintering temperature (for example, 1000° C. to 1300° C.) of the piezoelectric material 20. As a result, the sintered piezoelectric pillars 400 are obtained. The piezoelectric pillars 400 illustrated in FIG. 1D are obtained by selectively heating the piezoelectric material 20 to the sintering temperature while preventing the mold 10 from being heated up to the sintering temperature.

When the temperature of the mold 10 is raised up to the sintering temperature of the piezoelectric material 20, the mold 10 is melted before the piezoelectric material 20 is sintered, or thermal deformation of the mold 10 occurs at near sintering temperature, resulting in the mold 10 being warped or broken. When the mold 10 is warped or broken, the piezoelectric material 20 cannot maintain its initial shape and the mold 10 cannot be used any longer but must be removed.

Therefore, in the manufacturing method according to the preferred embodiment of the present invention, the piezoelectric pillars 400 are formed by heating only the piezoelectric material 20 to be sintered, with the mold 10 remaining unheated or less heated. The manufacturing method of the piezoelectric element in accordance with the preferred embodiment of the present invention has an advantage of preventing the thermal deformation of the mold 10 so that the piezoelectric material 20 can maintain its initial shape and the mold 10 can be used as it is after the sintering of the piezoelectric material 20 is performed because only the piezoelectric material 20 is heated to the sintering temperature.

The selective heat treatment which means a process of heating only the piezoelectric material 20 without heating the mold 10 will be described in detail later.

At least a part of the technologies used in the method of manufacturing a piezoelectric element according to the preferred embodiment of the present invention as described above may be applied to an electronic device including a piezoelectric element and a method of manufacturing the electronic device. For example, an electronic device including a piezoelectric element according to an exemplary embodiment of the present invention includes a mold 10, a first electrode 200 provided on an upper surface of the mold 10, and a second electrode 300 provided on a lower surface of the mold 10, and at least one piezoelectric pillar 400 provided between the first electrode 300 and the second electrode 300 and made of a piezoelectric material. The mold 10 is not heated to a sintering temperature, and only the piezoelectric material is heated to the sintering temperature so as to be sintered.

Hereinafter, an embodiment in which an anodic oxide film 100 is used as the mold 10 will be described. An electronic device including a piezoelectric element according to an exemplary embodiment of the present invention includes an anodic oxide film 100, a first electrode 200 provided on the upper surface of the anodic oxide film 100, a second electrode provided on the lower surface of the anodic oxide film 100, and at least one piezoelectric pillar 400 embedded in the anodic oxide film 100 and disposed between the first electrode 200 and the second electrode 300. The piezoelectric pillar 400 is formed by heating a piezoelectric material charged in a hole formed in the anodic oxide film 100 to a sintering temperature so that the piezoelectric material can be sintered.

A method of manufacturing an electronic device including a piezoelectric element according to an embodiment of the present invention includes: preparing an anodic oxide film 100; forming filling holes 150 extending through the anodic oxide film 100 from an upper surface to a lower surface of the anodic oxide film 100 in a manner that the filling holes 150 are separated from pores 110 that naturally occur in the anodic oxide film 100 during the preparation of the anodic oxide film 100; forming piezoelectric pillars 400 by filling the filling holes 150 with a piezoelectric material; forming a first electrode 200 on the upper surface of the anodic oxide film 100 in a manner to be in contact with the piezoelectric pillars 400; and forming a second electrode 300 on the lower surface of the anodic oxide film 100 in a manner to be in contact with the piezoelectric pillars 400. Specifically, in the forming of the piezoelectric pillars 400, the piezoelectric material 20 charged into the filling holes 150 is selectively heated to the sintering temperature of the piezoelectric material 20 so as to be sintered.

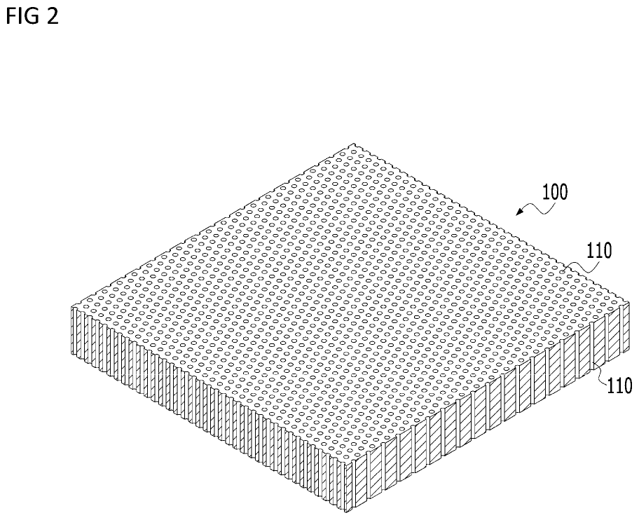

The process of preparing the anodic oxide film 100 constituting the piezoelectric element according to an exemplary embodiment of the present invention will be described with reference to FIG. 2.

The process of preparing the anodic oxide film 100 includes anodizing a base metal to form an oxide layer on top of the base metal and removing the base metal.

The anodic oxide film 100 refers to the oxide layer formed by anodizing the base metal. In addition, the pores 110 refer to holes that are naturally generated during the anodizing. The generated pores 110 are regularly arranged.

When the base metal is aluminum (Al) or an aluminum alloy, the oxide layer (anodic oxide film) 100 formed on the base metal through the anodizing is anodized aluminum oxide (Al₂O₃). The oxide layer formed on top of the base metal is composed of a barrier layer in which the pores 110 are not formed and a porous layer in which the pores 110 are formed. The barrier layer is disposed on the base metal, and the porous layer is disposed on the barrier layer.

When the base metal is removed after the completion of the anodizing reaction, only the anodic oxide film 100 (i.e., anodized aluminum oxide (Al₂O₃)) consisting of the barrier layer and the porous layer remains. The barrier layer is removed, and only the porous layer remains as illustrated in FIG. 2. The porous layer will be referred to as the anodic oxide film 100 in some cases. The anodic oxide film 100 has a composition of Al₂O₃ and is overall a thin plate. The anodic oxide film 100 has an array of vertical pores 110 having a uniform diameter and being regularly arranged. The anodic oxide film 100 that remains after the base metal portion and the barrier layer portion are removed can be used as the mold 10.

Each pore 110 is present independently of each other in the anodic oxide film 100. In other words, in the anodic oxide film 100 made of anodized aluminum oxide (Al₂O₃), a number of pores 110 having an inner diameter of several nm to several hundred nm are formed to pass through the anodic oxide film 100 from the upper surface to the lower surface of the anodic oxide film 100.

Alternatively, the anodic oxide film 200 including the barrier layer as well as the porous layer may be used as the mold 10. In this case, one end of each of the pores 110 is closed by the barrier layer.

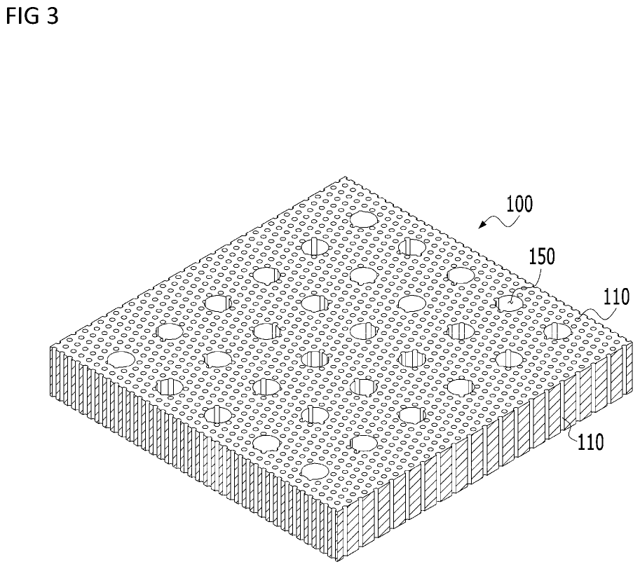

Next, as illustrated in FIG. 3, the filling holes 150 that are independent of the pores 110 that naturally occur during the anodizing of the base metal are formed in the anodic oxide film 100. The filling holes 150 are formed to pass through the anodic oxide film 100 from the upper surface to the lower surface of the anodic oxide film 100.

The filling holes 150 are formed by selectively etching the anodic oxide film 100. The anodic oxide film 100 is partially masked, and only the unmasked regions are etched to form the filling holes 150. By using the etching process, it is possible to easily form the filling holes 150 that have a larger inner diameter than the pores 110 and which perpendicularly pass through the anodic oxide film 100 from the upper surface to the lower surface because an etching solution reacts with the anodic oxide film 100. The pores 110 and the filling holes 150 are arranged in parallel with each other and have a perpendicular through-hole shape. Since the filling holes 150 are through-holes perpendicular to the surface of the anodic oxide film, the piezoelectric pillars 400 formed in the filling holes 150 have a perpendicular pillar shape.

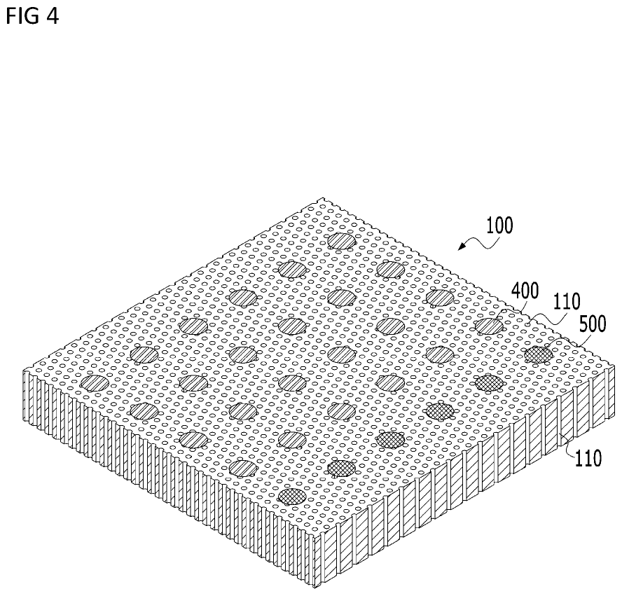

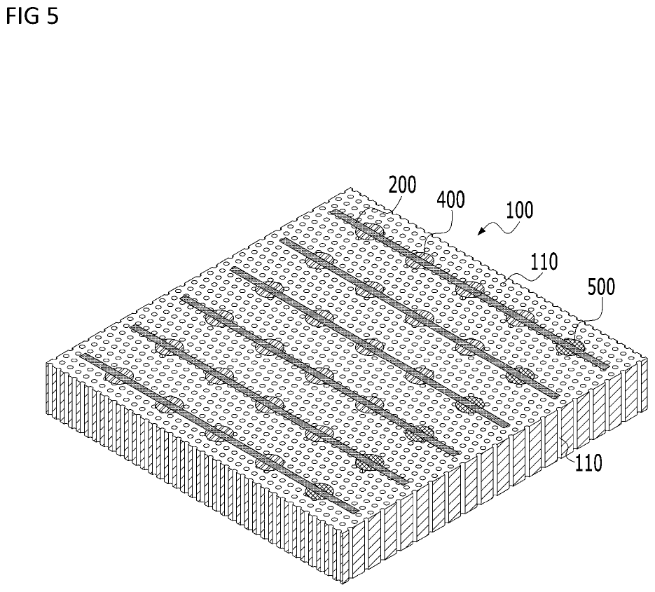

Next, as illustrated in FIG. 4, the piezoelectric material is charged into the filling holes 150. The piezoelectric material is a material that converts a mechanical force into an electrical signal or converts an electrical signal into a mechanical force. In the embodiment of the present invention, the piezoelectric material is a piezoelectric ceramic. For example, it is a PZT-based material such as a solid solution of zinc titanate (Pb(Zr, Ti)O₃) or lead zinc niobate (Pb(Zn, Nb)O₃) and lead titanate (PbTiO₃), a solid solution of magnesium lead niobate (Pb(Mg, Nb)O₃) and lead titanate (PbTiO₃). However, the piezoelectric material is not limited thereto.

According to one embodiment of the present invention, the filling holes 150 are through-holes, each extending from the upper surface to the lower surface of the anodic oxide film 100. However, the shape of the filling holes 150 is not limited thereto. In a case where the filling holes 150 to be filled with the piezoelectric material 20 are holes with a closed bottom end, it is difficult to perfectly fill the filling holes 150 with a piezoelectric material due to the pressure of air in the filling holes 150. On the other hand, in a case where the filling holes 150 are open at both ends thereof, the filling holes 150 can be easily perfectly filled with a piezoelectric material. In the case in which the filling holes 150 are through-holes being open at both ends thereof, a vacuum pump may be installed on one side of the anodic oxide film 100 so as to suck air from the filling holes 150, thereby generating a negative pressure in the filling holes 150. In this case, the piezoelectric material 20 can easily flow into the filling holes 150. With this configuration, the filling holes 150 can be perfectly filled with a piezoelectric material without voids occurring. Therefore, the uniformity and durability of the piezoelectric pillars 400 thus formed are improved.

After the piezoelectric material 20 is charged into the filling holes 150, only the piezoelectric material is heated to a sintering temperature to produce the piezoelectric pillars 400. In other words, the piezoelectric pillars 400 embedded in the anodic oxide film 100 are formed by sintering the piezoelectric material charged into the filling holes 150 by heating the piezoelectric material to the sintering temperature.

The piezoelectric pillars 400 are disposed in the perpendicular through-holes (filling holes) 150 formed in the anodic oxide film 100. That is, the piezoelectric pillars 400 are surrounded by the anodic oxide film 100 having pores formed therein. Since the anodic oxide film 100 is not electrically conductive, an additional insulating layer for the first and second electrodes 200 and 300 is not required.

With this configuration, since ultrasonic waves generated at around the side surfaces of adjacent piezoelectric pillars 400 are effectively attenuated by air pillars (i.e., the pores 110), noise caused by the adjacent piezoelectric pillars 400 can be effectively removed.

In addition, the anodic oxide film 100 has numerous pores 110. That is, the density of the anodic oxide film 100 is low. Therefore, a piezoelectric element configured with the anodic oxide film 100 has a low acoustic impedance due to the low density. Conventionally, it is required that a low acoustic impedance material such as synthetic resin, polymer, or epoxy be provided at around each piezoelectric pillar to manufacture a piezoelectric element having a low acoustic impedance. However, since the anodic oxide film 100 used in the embodiment of the present invention has a low acoustic impedance due to the numerous pores 110, it is possible to easily manufacture a piezoelectric element having a low acoustic impedance with the use of the anodic oxide film 100, without using an additional low acoustic impedance material such as synthetic resin, polymer, or epoxy.

In addition, since the filling holes 150 to be filled with the piezoelectric material 20 are formed by etching the anodic oxide film 100, it is easy to form the piezoelectric pillars 400 having an optimized aspect ratio that enables piezoelectric properties to be well exhibited. In addition, since the piezoelectric pillars 400 having a high aspect ratio and a small cross-sectional area can be manufactured, the piezoelectric efficiency of the piezoelectric element thus manufactured can be improved.

In addition, since the filling holes 150 are formed by etching the anodic oxide film 100, the shape, arrangement, density, and the like of the filling holes 150 can be easily controlled.

An electronic device including the piezoelectric element described above can utilize the favorable characteristics of the anodic oxide film 100.

After the manufacturing of the piezoelectric element, a conductive material is charged into the remaining filling holes that are not filled with the piezoelectric material. In order to charge the conductive material into the remaining filling holes 150, a mask-assisted sputtering process, an atomic layer deposition (ALD) process, or the like is used. Besides those methods, other methods can be used to fill the filling holes 150 with the conductive material when possible. Since the conductive material is charged into the perpendicular filling holes 150, conductive pillars 500 perpendicular to the surface of the anodic oxide film are formed. The conductive pillar 500 connects at least one of the first electrode 200 to at least one of the second electrode 300 to be described later.

Since the conductive pillar 500 connects the first electrode 200 provided on the upper surface of the anodic oxide film 100 to the second electrode 300 provided on the lower surface of the anodic oxide film 100, when an electronic device equipped with the piezoelectric element is electrically connected to a circuit board or a control chip, the electronic device can be electrically connected through flip-chip bonding instead of wire bonding.

The conductive pillars 500 are formed to fill the respective perpendicular through-holes extending through the anodic oxide film 100 from the upper surface to the lower surface of the anodic oxide film 100, the conductive pillars 500 are surrounded by the anodic oxide film 100. The anodic oxide film 100 having numerous pores 110 has a heat insulating function of blocking heat transfer in the horizontal direction. Therefore, the conduction of heat generated from the conductive pillars 500 during the use of the electronic device is blocked by the anodic oxide film 100. That is, it is possible to prevent the piezoelectric pillars 400 from being thermally deformed by the heat generated from the nearby conductive pillars. This prevents the occurrence of noise.

In addition, since the piezoelectric pillars 400 and the conductive pillars 500 are both formed to fill the filling holes 150 passing through the anodic oxide film 100 from the upper surface to the lower surface, each of the piezoelectric pillars 400 and the conductive pillars 500 is surrounded by the anodic oxide film 100. For this reason, the lateral deformation of the piezoelectric pillars 400 and the conductive pillars 500 can be prevented, and the electronic device can be miniaturized without deterioration of the durability thereof.

The piezoelectric pillars 400 and the conductive pillars 500 are arranged in a matrix of m rows and n columns. Referring to FIG. 4, the piezoelectric pillars 400 are arranged in six rows and four columns, and the conductive pillars 500 are arranged in one row at the rightmost side. That is, the piezoelectric pillars 400 and the conductive pillars 500 are arranged in an overall array of 6 rows and 5 columns.

Alternatively, although not illustrated in the drawings, the conductive pillars 500 may be disposed between a first group of piezoelectric pillars 400 and a second group of piezoelectric pillars 400, unlike the configuration in which the conductive pillars 500 are arrayed to form a column in which each of the conductive pillars 500 is disposed at the right end of a corresponding one of the rows of piezoelectric pillars 400. When the conductive pillars 500 are disposed in the middle, it is possible to reduce the length of the first electrode 200 that extends up to the outermost piezoelectric pillar 400 from the conductive pillar 500, thereby reducing a voltage drop that increases with the length of the first electrode 200.

On the other hand, although not illustrated in the drawings, the conductive pillars 500 may be disposed alternately at the rightmost side for one row of the piezoelectric pillars 400 and at the leftmost side for the next row of the piezoelectric pillars 400. In other words, the conductive pillars 500 may be classified as first conductive pillars corresponding to the respective odd-numbered rows of the piezoelectric pillars 400 and second conductive pillars corresponding to the respective even-numbered rows of the piezoelectric pillars 400. For example, each of the first conductive pillars is disposed at a first end (for example, right end) of a corresponding one of the odd-numbered rows of the piezoelectric pillars 400 and each of the second conductive pillars is disposed on a second end (for example, left end) of a corresponding one of the even-numbered rows of the piezoelectric pillars 400. With this arrangement, the piezoelectric pillars 400 can be controlled row by row or column by column.

Although not illustrated in the drawings, multiple conductive pillars 500 may be provided for one first electrode of a plurality of first electrodes. In this case, even though any one of the conductive pillars 500 malfunctions, the electronic device equipped with the piezoelectric element can normally operate.

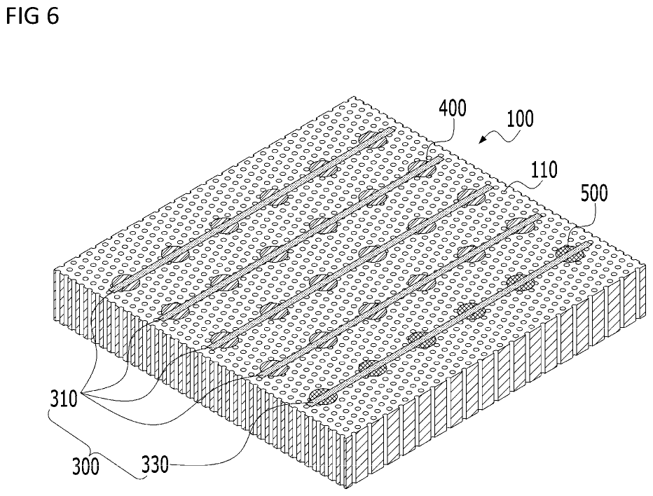

Next, an embodiment in which the first electrodes 200 provided on the upper surface of the anodic oxide film 100 are arranged to cross the second electrodes 300 provided on the lower surface of the anodic oxide film 100 will be described with reference to FIGS. 5 and 6. That is, each of the first electrode 200 extends in a first direction (for example, horizontal direction) on the upper surface of the anodic oxide film 100, and each of the second electrodes 300 extends in a second direction (vertical direction) on the lower surface of the anodic oxide film 100. The piezoelectric pillars 400 made of a piezoelectric material are provided between the first electrodes 200 and the second electrodes 300, and the conductive pillars 400 made of a conductive material are also disposed between the first electrodes 200 and the second electrodes 300.

At least either one of the first electrode 200 and the second electrode 300 includes a conductive material. For example, at least either one of the first electrode 200 and the second electrode 300 includes a metal oxide such as indium tin oxide, indium zinc oxide, copper oxide, tin oxide, zinc oxide, or titanium oxide. Alternatively, at least either one of the first electrode 200 and the second electrode 300 may include a nanowire, a photosensitive nanowire film, carbon nanotubes (CNT), graphene, a conductive polymer, or a mixture thereof. Alternatively, at least either one of the first electrode 200 and the second electrode 300 may include various metals. For example, the first electrode 200 may include at least one material selected from the group consisting of chromium (Cr), nickel (Ni), copper (Cu), aluminum (Al), silver (Ag), molybdenum (Mo), Gold (Au), titanium (Ti), and alloys thereof. Alternatively, at least either one of the first electrode 200 and the second electrode 300 is a mesh-shaped electrode.

At least either one of the first electrode 200 and the second electrode 300 is formed through a sputtering process on the surface of the anodic oxide film 100.

Referring to FIG. 5, the first electrodes 200 are formed on the upper surface of the anodic oxide film 100. The first electrodes 200 are arranged in parallel with and spaced from each other. As illustrated in the drawings, the piezoelectric pillars 400 and the conductive pillars 500 are arranged in an array of 6 rows and 5 columns, and the first electrodes 200 are in contact with the upper surfaces of the piezoelectric pillars 400 and the conductive pillar 500 that are arranged in a row direction. Accordingly, as illustrated in FIG. 5, the number of the first electrodes is six. That is, the number of the first electrodes is equal to the number of the conductive pillars 500.

FIG. 6 is a perspective view illustrating the lower surface of the anodic oxide film 100 of FIG. 5. Referring to FIG. 6, the second electrodes 300 are formed on the lower surface of the anodic oxide film 100, and the first electrodes 200 and the second electrodes 300 are arranged to cross each other with the anodic oxide film 100 provided therebetween in the height direction. Here, among the second electrodes 300, the second electrodes 300 connected to the lower ends of the piezoelectric pillars 400 are referred to as first-group second electrodes 310 and the second electrode 300 connected to the lower ends of the conductive pillars 500 is referred to as a second-group second electrode 330.

In the manufacturing method for the piezoelectric element and the electronic device described above, the filling holes 150 that are perpendicular through-holes extending through the anodic oxide film 100 from the upper surface to the lower surface are formed, and then the filling holes 10 are filled with a piezoelectric material. However, alternatively, instead of the perpendicular through-holes, bottom-end-closed holes may be formed in the anodic oxide film 100 including the barrier layer by which the bottom ends of the holes are closed. Then, the bottom-end-closed holes are filled with a piezoelectric material, and then the barrier layer is removed so that the bottom end of the piezoelectric material 20 appears through the lower surface of the anodic oxide film 100.

In other words, a method of manufacturing an electronic device including a piezoelectric element according to an embodiment of the present invention includes: preparing an anodic oxide film 100; forming filling holes 150 that are separated from pores that are naturally generated during the preparing of the anodic oxide film 100, in the anodic oxide film 100; forming piezoelectric pillars 400 by filling the filling holes 150 with a piezoelectric material; removing a lower portion of the anodic oxide film 100 so that the lower ends of the piezoelectric pillars 400 can be exposed; forming first electrodes 200 in contact with the piezoelectric pillars 400 on the upper surface of the anodic oxide film 100; and forming second electrodes 300 in contact with the piezoelectric pillars 400 on the lower surface of the anodic oxide film 100. In this method, the forming of the piezoelectric pillars 400 includes a step of selectively heating the piezoelectric material charged in the filling holes 150 to a sintering temperature so that the piezoelectric material can be sintered.

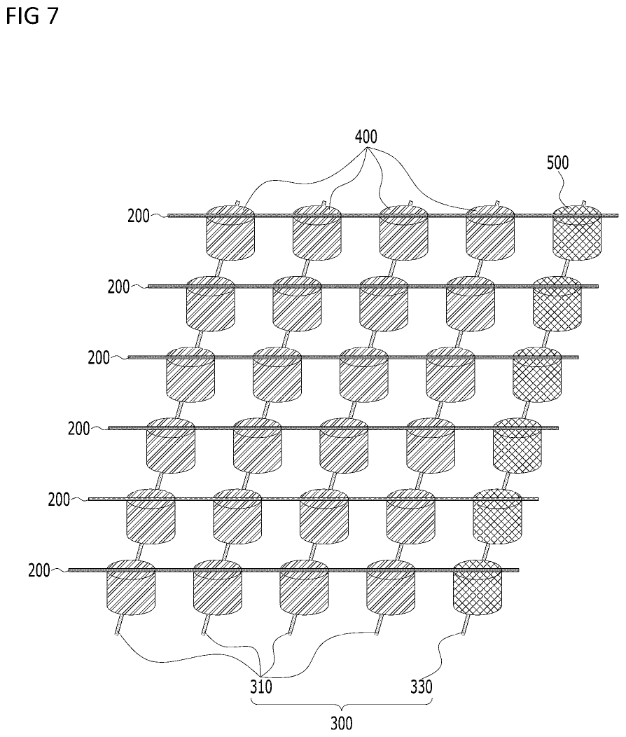

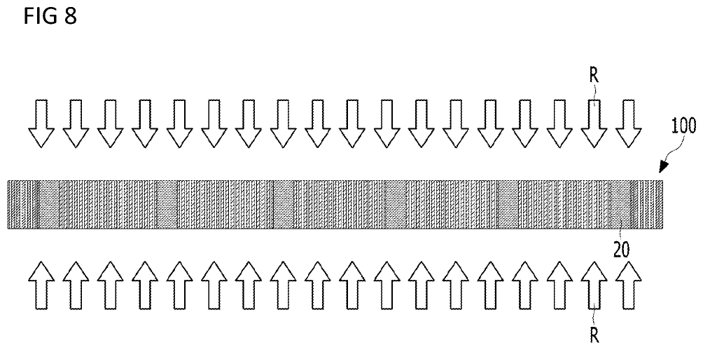

FIG. 7 schematically illustrates an electronic device including a piezoelectric element according to a preferred embodiment of the present invention, with an anodic oxide film 100 omitted from the illustration. As illustrated in FIG. 7, the piezoelectric pillars 400 are provided between the first electrode 200 and the first-group second electrode 310, and the conductive pillars 500 are provided between the first electrode 200 and the second-group second electrode 330.

One second-group second electrode 330 is connected to a plurality of (for example, five) first electrodes 200 via a plurality of (for example, five) conductive pillars 500. That is, one second-group second electrode 330 is electrically connected to the multiple first electrodes 200. Therefore, the multiple first electrodes 200 can be collectively controlled via one second-group second electrode 330.

In addition, due to the configuration in which the second-group second electrode 330 is connected to the first electrodes 200 via the conductive pillars 500, an electronic device including the piezoelectric element can be electrically connected to a circuit board or a control chip through flip-chip bonding, without requiring an additional wire bonding process.

Hereinafter, a method of selectively heating only the piezoelectric material 20 to a sintering temperature will be described with reference to FIGS. 8 to 12.

The selective heat treatment may be performed using a rapid thermal process (RTP).

As illustrated in FIG. 8, the rapid thermal process refers to a process of directing light rays R emitted from a lamp (for example, a tungsten halogen lamp) to an object. Since the piezoelectric material 20 according to the preferred embodiment of the present invention is a black or near black, and the anodic oxide film 100 is white or near white, there is a difference in absorption of the light rays R between the piezoelectric material 20 and the anodic oxide film 100. That is, the piezoelectric material 20 charged in the filling holes 150 absorbs the light rays R emitted from the lamp of the rapid heat treatment apparatus and rapidly increases in temperature within a short time. On the other hand, since the anodic oxide film 100 rarely absorbs the light rays R emitted from the lamp of the rapid heat treatment apparatus, an increase in the temperature of the anodic oxide film 100 is relatively small in comparison with the piezoelectric material 20.

Alternatively, the surface of the anodic oxide film 100 may be provided with a reflective layer to reflect the light rays R. Thus, the anodic oxide film 100 may not absorb the light rays R emitted from the lamp of the rapid heat treatment apparatus. In addition, the surface of the piezoelectric material 20 may be provided with an absorptive layer to absorb the light rays R. With this configuration, the piezoelectric material 20 can more easily absorb the light rays R emitted from the lamp of the rapid heat treatment apparatus.

Within a temperature increasing period controlled by the rapid heat treatment apparatus, the piezoelectric material 20 relatively rapidly rises to a high temperature than the anodic oxide film 100. That is, the piezoelectric material 20 rapidly reaches a sintering temperature (for example, 1000° C. to 1300° C.). At this time, the anodic oxide film 100 reaches a relatively low temperature (for example, 200° C. to 300° C.). Therefore, the anodic oxide film 100 maintains its original shape without being thermally deformed and thus functions as a mold under the same temperature conditions as the sintering conditions of the piezoelectric material 20. Under the temperature conditions, only the piezoelectric material 20 is sintered at the sintering temperature to form the piezoelectric pillars 150.

Furthermore, in the rapid thermal process, it is preferable to simultaneously emit the light rays R to both the upper and lower surfaces of the anodic oxide film 100 with the holes filled with the piezoelectric material 20. When only one side of the anodic oxide film 100 is irradiated with the light rays R, the anodic oxide film 100 is likely to be warped due to the temperature difference between the upper surface and the lower surface of the anodic oxide film 100. However, when the upper and lower sides of the anodic oxide film 100 are simultaneously irradiated with the light rays R, since the temperature difference between the upper surface and the lower surface of the anodic oxide film 100 is small, warping deformation of the anodic oxide film 100 is prevented.

When the temperature of the anodic oxide film 100 reaches the sintering temperature (for example, 1000° C. to 1300° C.) of the piezoelectric material 20, the anodic oxide film 100 experiences thermal deformation. That is, the anodic oxide film 100 is warped or cracks. However, according to the preferred embodiment of the present invention, since only the piezoelectric material 20 is selectively heated to the sintering temperature, the thermal deformation of the anodic oxide film 100 is prevented. Therefore, the anodic oxide film 100 used to form the piezoelectric pillars can be used without being discarded.

In the case of heating the piezoelectric material 20 using a furnace, the piezoelectric material 20 shrinks due to a long sintering time. Thus, the piezoelectric material 20 cannot maintain the initial shape thereof. When the rapid thermal process is used, the piezoelectric material 20 provided in the filling holes formed in the anodic oxide film 100 can be sintered while maintaining its initial shape and preventing the thermal deformation of the anodic oxide film 100.

When the thermal process is performed for a long period, the surface and the inside of the piezoelectric material 20 have a similar sintered density and the piezoelectric material 20 shrinks overall. In this case, the piezoelectric pillars 400 formed through the sintering cannot maintain the same shape as the filling holes 150 formed in the anodic oxide film 100, and thus cannot function properly as the piezoelectric pillars 400. In addition, a long period of thermal process will cause thermal deformation of the mold (i.e., anodic oxide film) 10.

Therefore, it is preferable to use the rapid thermal process for heating the piezoelectric material. In this case, the duration of the rapid thermal process preferably ranges from 1 minute to 5 minutes, and the target heating temperature of the piezoelectric material 20 during the rapid thermal process preferably ranges from 700° C. to 1300° C.

When such a rapid thermal process condition is set, it is possible to minimize the time during which the heat is conducted from the piezoelectric material 20 to the surroundings after the piezoelectric material 20 is heated. Therefore, it is possible to prevent the surrounding anodic oxide film 100 from being deformed due to heat conduction. In addition, since the sintered density of an end portion of the piezoelectric material 20 provided in the filling hole 150 is higher than the sintered density of the center of the piezoelectric material 20, the piezoelectric pillar 400 can maintain the initial shape of the piezoelectric material 200 that is charged into the filling hole 150.

As such, the process of selectively heating the piezoelectric material 20 to the sintering temperature means that the light rays R are emitted from the lamp only to the piezoelectric material 20 provided in the filling holes 150 of the anodic oxide film 100 so that the piezoelectric material 200 can absorb the light rays R. Through this process, only the piezoelectric material 20 is heated to the sintering temperature.

When the rapid thermal process (RPT) is used for the selective heat treatment, a mask 1000 having a pattern portion 1100 and a patternless portion 1200 may be used.

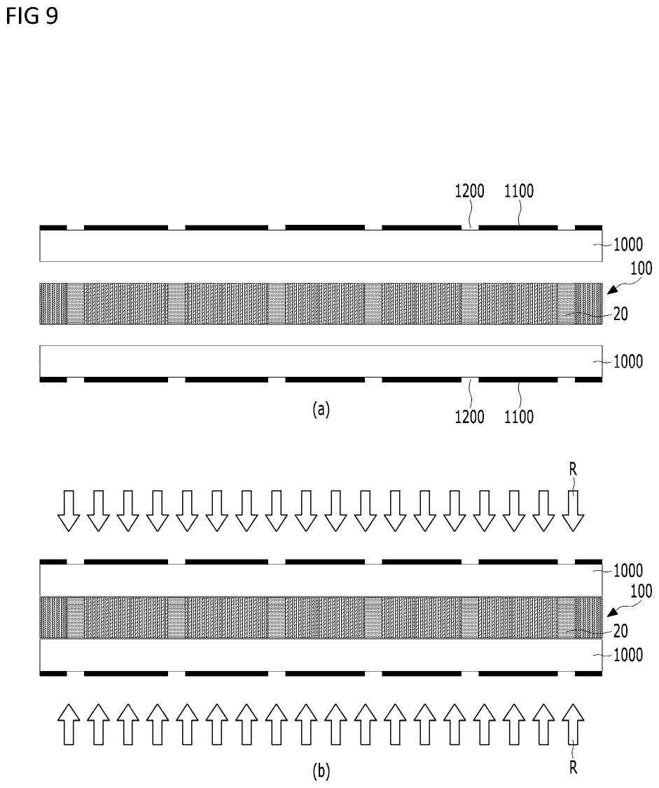

FIG. 9A illustrates a state in which the anodic oxide film 100 provided with the piezoelectric material 20 is aligned with the mask 100, and FIG. 9B illustrates a state in which the rapid thermal process is performed, with the mask 100 placed on the anodic oxide film 100 provide with the piezoelectric material 20.

The mask 1000 is made of a transparent material with respect to the light rays R. For example, the mask 1000 is made of quartz.

The pattern portion 1100 is provided on at least one surface of the mask 1000. The pattern portion 1100 is provided at a position corresponding to the region of the anodic oxide film 100. The pattern portion 1100 reflects or absorbs the light rays R, thereby blocking the transmission of the light rays R to the anodic oxide film 100. Therefore, the pattern portion 1100 is made of an arbitrary light reflective material or an arbitrary light absorbing material.

The patternless portion 1200 is provided at a position corresponding to the region of the piezoelectric material 20. The patternless portion 1200 is provided between the pattern portions 1100, thereby allowing the light rays R to pass through.

The mask 1000 may be provided above and below the anodic oxide film 100 provided with the piezoelectric material 20. With this arrangement of the mask 1000, the piezoelectric material 20 can be heated from both sides, i.e., from above and below. Therefore, the piezoelectric material 20 can be rapidly heated to the sintering temperature, and the top and bottom of the piezoelectric material 20 can be more uniformly sintered.

The mask 1000 positioned above the anodic oxide film 100 has the pattern portion 1100 on the upper surface thereof, and the mask 1000 positioned below the anodic oxide film 100 has the pattern portion 1100 provided on the lower surface thereof. The pattern portion 1100 of the mask 1000 is spaced from the anodic oxide film 100. With this arrangement, the light rays R passing through the patternless portion 1200 can be incident on a wider region than the opening area (the patternless portion) 1200. Therefore, the piezoelectric material 20 can be more effectively sintered even when there is a slight positioning error between the anodic oxide film 100 provided with the piezoelectric material 20 and the mask 100.

When the pattern portion 1100 is made of a light absorbing material that absorbs the light rays R and is formed on a surface facing the anodic oxide film 100 (for example, when the pattern portion 1100 is provided at a lower portion of the mask 1000 positioned above the anodic oxide film 100 or the pattern portion 1100 is provided at an upper portion of the mask 1000 positioned below the anodic oxide film 100), the anodic oxide film 100 may be heated due to heat conduction between the pattern portion 1100 and the anodic oxide film 100. However, according to the preferred embodiment of the present invention, since the pattern portion 1100 of the mask 1000 is spaced apart from the anodic oxide film 100 provided with the piezoelectric material 20 at a predetermined interval, it is possible to prevent the anodic oxide film 100 from being heated by thermal conduction attributable to direct contact.

In addition, a guide member (not illustrated) may be provided to allow the light rays R to be guided only to the piezoelectric material 20. The guide member (not illustrated) may be configured such that the light rays R are not guided to the anodic oxide film 100 but are guided only to the piezoelectric material 20.

The selective heat treatment may be performed by using a high frequency heating apparatus.

The high frequency heating preferably heats only the piezoelectric material 20 to the sintering temperature through dielectric heating, microwave heating, or both.

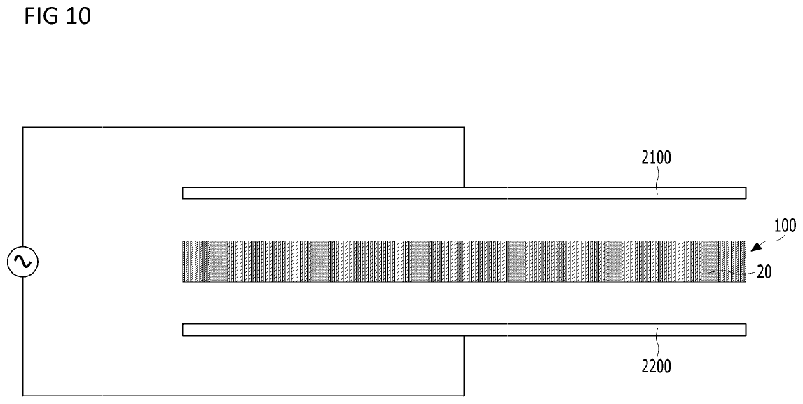

The high frequency heating apparatus shown in FIG. 10 selectively heats only the piezoelectric material 20 to the sintering temperature by using dielectric heating. When the anodic oxide film 100 provided with the piezoelectric material 20 is positioned between two electrodes 2100 and 2300 and a high frequency voltage (for example, several MHz or higher) is applied across the two electrodes 2100 and 2300, dipoles constituting the piezoelectric material 20 change in direction in accordance with alternating electric fields, and thus the dipoles vibrate to generate frictional heat. That is, the piezoelectric material 20 is heated. By increasing the frequency and the voltage, instantaneous heating (rapid heating) can be effectively performed. When a time for dielectric recovery is longer than a period for a single cycle of the frequency, the rate of change in the polarization direction of the dipoles is lower than the recovery rate and thus the heating efficiency is lowered. Therefore, the application frequency needs to be optimally controlled.

The frequency applied by the high frequency heating apparatus needs to be used only for the purpose of the temperature increase of the piezoelectric material 20. Thus, the frequency is a piezoelectric material-dedicated frequency that is selected within a frequency range not to increase the temperature of the anodic oxide film 100. That is, the piezoelectric material-dedicated frequency is a frequency at which only the piezoelectric material 20 undergoes temperature rising while preventing the anodic oxide film 100 from being heated. Therefore, with the use of the piezoelectric material-dedicated frequency, it is possible to selectively heat only the piezoelectric material provided in the filling holes 150 to the sintering temperature so that the piezoelectric material 20 can be sintered.

The process of selectively heating the piezoelectric material to the sintering temperature may include: placing the piezoelectric material between the electrodes in a state where the piezoelectric material is charged into the filling holes 150 formed in the anodic oxide film 100; and applying a high frequency voltage across the electrodes 2100 so that dipoles constituting the piezoelectric material 20 change in their direction in accordance with alternating electric fields. Thus, the dipoles vibrate to generate frictional heat.

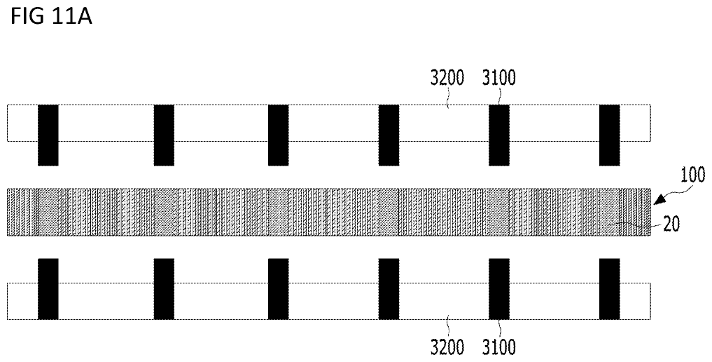

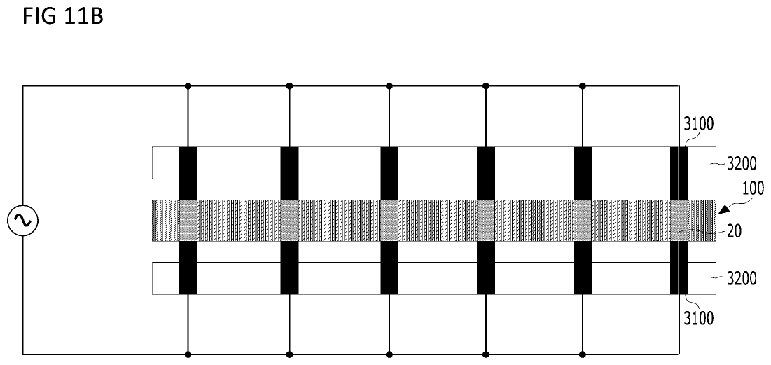

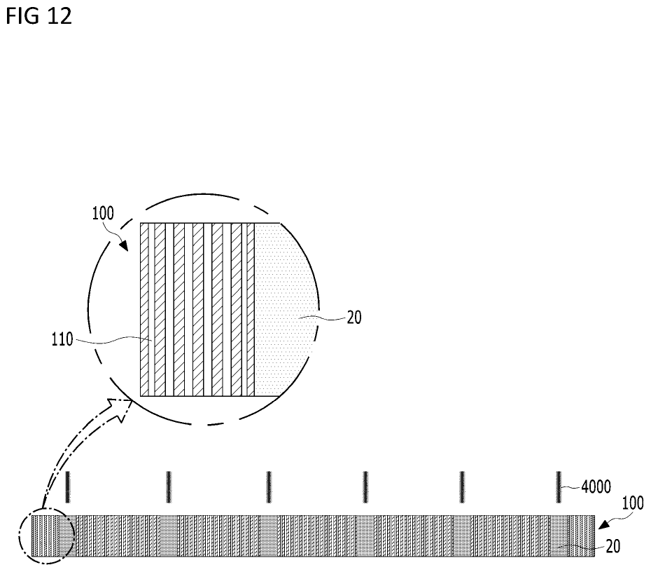

On the other hand, as illustrated in FIG. 11A and FIG. 11B, a high frequency heating apparatus may include a plurality of electrodes 3100. The electrodes 3100 are disposed at positions corresponding to the regions of the piezoelectric material 20, and an insulator 3200 is provided between each of the individual electrode 3100 so that the electrodes 3100 are insulated from each other. The insulator 3200 not only insulates each electrode 3100 but also fixes each electrode 3100 not to be movable.

The electrodes 3100 are positioned to correspond to the regions of the piezoelectric material 20. A high frequency electric field is generated between the upper and lower electrodes 3100 due to the configuration in which the electrodes 3100 are positioned to correspond to the positions of the piezoelectric material 20. Since the piezoelectric material 20 is positioned within a high frequency electric field area formed between the upper and lower electrodes 3100, only the piezoelectric material 20 can be selectively heated to the sintering temperature.

Alternatively, the selective heat treatment may be performed using a laser heating apparatus. Referring to FIG. 12, only the piezoelectric material 20 may be selectively heated to the sintering temperature by emitting a laser beam 4000 to the anodic oxide film 100 provided with the piezoelectric material 20. The laser beam 4000 is selectively emitted only to the piezoelectric material 20 to heat the piezoelectric material 20. The laser beam 4000 sequentially scans each of a plurality of regions of the piezoelectric material 20 so that the plurality of regions of the piezoelectric material 20 can be sequentially heated, or a plurality of laser beams 4000 may be simultaneously emitted to the plurality of regions of the piezoelectric material 20 so that the plurality of regions of the piezoelectric material 20 can be collectively heated.

As described above, the preferred embodiment of the present invention employs a technique in which only the piezoelectric material 20 is selectively heated to the sintering temperature, thereby preventing thermal deformation of the anodic oxide film 10 and maintaining the initial shape of the piezoelectric pillar 150 after the piezoelectric material 20 is sintered to form the piezoelectric pillar 150. Therefore, the anodic oxide film 100 needs not be removed after the piezoelectric material 20 is sintered. That is, the anodic oxide film 100 can be used as it is as one element of the electronic device including the piezoelectric element according to the preferred embodiment of the present invention.

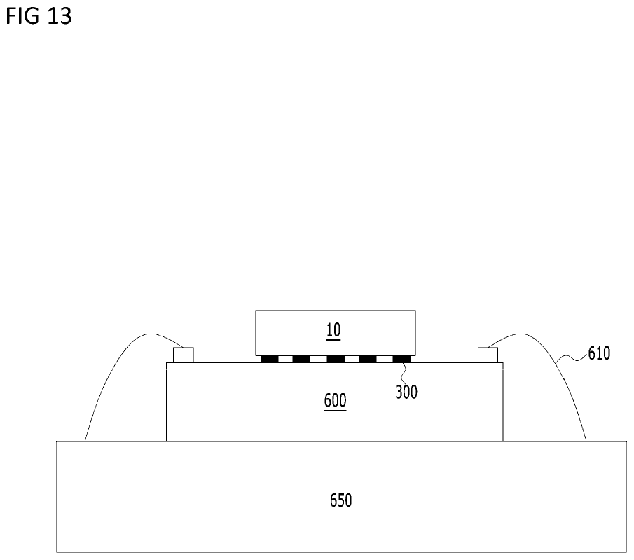

Referring to FIG. 13, a control chip 600 is provided on a circuit board 650 and is electrically connected to a circuit formed on the circuit board 650 via a wire 610, and an electronic device 10 using a piezoelectric element according to a preferred embodiment of the present invention is mounted on the control chip 600 through a flip-chip bonding process. A lower surface of the electronic device 10 is provided with a second electrode 300 through which electric power can be supplied to piezoelectric pillars 400 and signals can be output from the piezoelectric pillars 400. Therefore, the electronic device 10 can be flip-chip mounted on the control chip 600. Although not illustrated in the drawings, when a controller for driving the electronic device 10 is provided on the circuit board 650, the electronic device 10 can be directly flip-chip mounted on the circuit board 650.

As such, since a wire for electrically connecting the electronic device 10 to the circuit board 650 or the control chip 600 is not required, the mounting of the electronic device 10 is simplified and the electronic device 10 can be miniaturized.

In the above-described embodiment, the filling holes 150 extending through the anodic oxide film 100 from top to bottom up are formed, then the piezoelectric material is charged into a group of the filling holes 150 to form the piezoelectric pillars 400, and the conductive material is charged into the remaining filling holes 150 to form the conductive pillars 500. However, alternatively, the filling holes 150 may not be additionally formed, and the pores 110 formed in the anodic oxide film 100 may be used instead of the filling holes 150. In this case, the piezoelectric material 20 may be charged into a group of the pores 110 of the anodic oxide film 100 to form the piezoelectric pillars 400 and the conductive material is charged into the remaining pores 110 to form the conductive pillars 500. However, this case has a disadvantage in that it takes more time and cost to fill the pores with the piezoelectric material and the conductive material compared to the case in which the filling holes are filled with the piezoelectric material and the conductive material. On the other hand, since the pores 110 of the anodic oxide film 100 can be used as they are, the process of forming the filling hole 150 can be omitted.

In addition, according to the above-described embodiment, the upper and lower ends of the pores 110 are open as illustrated in the drawings. However, there is another embodiment in which the barrier layer is not removed to close the upper or lower end of the pores 110. According to this embodiment, it is easy to form the electrode on the upper surface of the barrier layer, and it is possible to prevent the strength of the anodic oxide film 110 from being reduced.

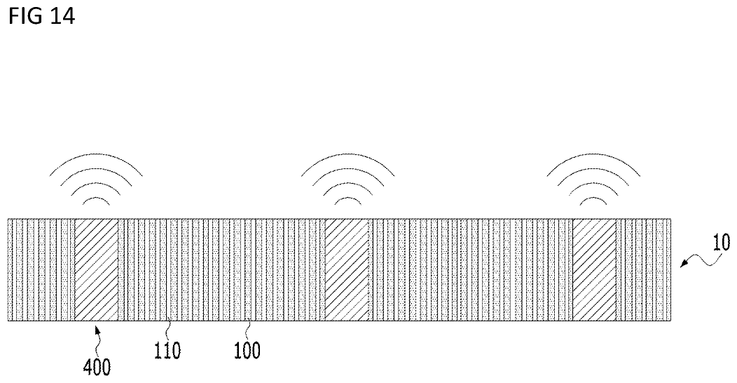

The electronic device including a piezoelectric element, according to the preferred embodiment of the present invention, may be a sound wave transmitter that generates sound waves by causing the piezoelectric pillars 400 to vibrate in a vertical direction. The vertical vibration of the piezoelectric pillars 400 is caused by applying a voltage across the electrodes respectively provided on the upper end and the lower end of each of the piezoelectric pillars 400 made of the piezoelectric material as illustrated in FIG. 14. This sound wave transmitter includes the configuration according to the preferred embodiment of the present invention.

In addition, the electronic device including a piezoelectric element, according to a preferred embodiment of the present invention, may be a speaker device that generates sound waves by causing the piezoelectric pillars 400 to vibrate in a vertical direction. The vertical vibration of the piezoelectric pillars 400 is caused by applying a voltage across the electrodes respectively provided on the upper end and the lower end of each of the piezoelectric pillars 400 made of the piezoelectric material. The speaker device includes the configuration according to the preferred embodiment of the present invention.

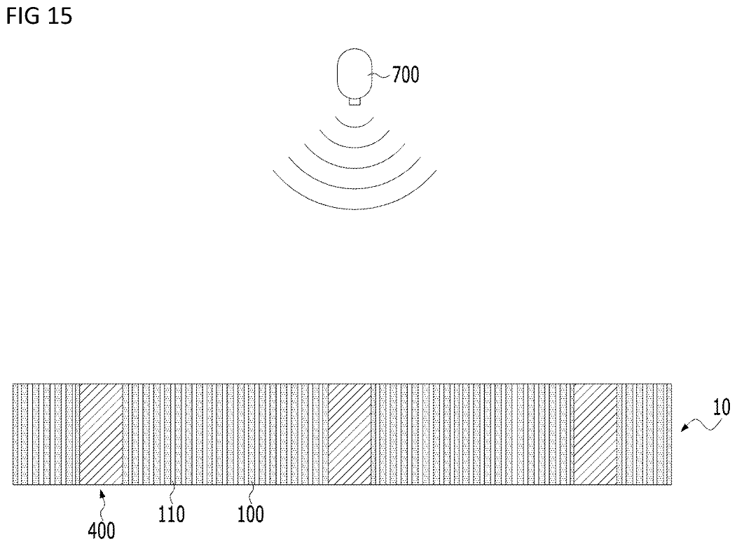

The electronic device including a piezoelectric material, according to the preferred embodiment of the present invention, may be a sound wave receiver that receives sound waves on the basis of the potential difference generated by the piezoelectric pillars 400 being deformed by the sound waves generated by an emitter 700 as illustrated in FIG. 15. The sound wave receiver includes the configuration according to the preferred embodiment of the present invention.

The electronic device including a piezoelectric element, according to a preferred embodiment of the present invention, may be a three-dimensional shape recognition device using ultrasonic waves. The three-dimensional shape recognition device includes the configuration according to the preferred embodiment of the present invention.

In this case, ultrasonic waves are generated by vibrating the piezoelectric pillars 400 in a vertical direction by applying a voltage having an ultrasonic band resonance frequency to the first and second electrodes 200 and 300 provided on the upper and lower surfaces of the piezoelectric pillars 400 made of a piezoelectric material. These ultrasonic waves reflect from the surface of a three-dimensional object and return to the shape recognition device. The returned ultrasonic waves deform the piezoelectric pillars 400, resulting in a change in potential. By using this potential change, the shape of the three-dimensional object is measured.

The piezoelectric pillars 400 transmit and receive ultrasonic waves in all directions including the transverse direction. The ultrasonic waves emitted from the side surfaces of the piezoelectric pillars 400 are not reflected from the three-dimensional object and are directly detected by the adjacent piezoelectric pillars 400. This means noise. The piezoelectric pillars 400 are provide in the filling holes 150 formed to vertically pass through the anodic oxide film 100 from the upper surface to the lower surface of the anodic oxide film 100, thereby being surrounded by the anodic oxide film 100 in which numerous pores 110 are formed. Therefore, ultrasonic waves generated from the side surfaces of the adjacent piezoelectric pillars 400 are effectively attenuated by a number of adjacent air pillars. Therefore, the signal noise generated by the adjacent piezoelectric pillars 400 can be effectively eliminated.

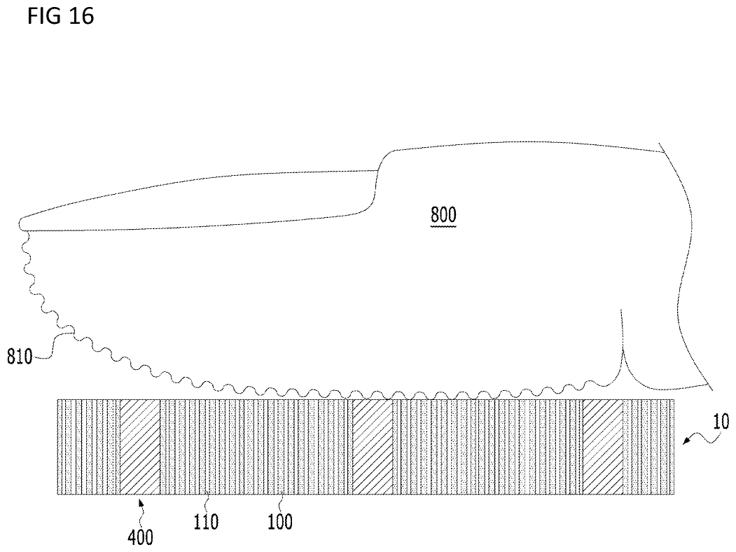

Referring to FIG. 16, the three-dimensional shape recognition device using ultrasonic waves may be an ultrasonic fingerprint sensor that recognizes the fingerprint 810 of a finger 800 or the biometric information of a finger 800. The ultrasonic fingerprint sensor has a merit that it can identify a fake fingerprint by three-dimensionally measuring the shape of a fingerprint unlike a conventional fingerprint recognition technique (for example, optical or capacitive) in which the shape of the fingerprint is two-dimensionally measured.

In addition, according to the preferred embodiment of the present invention, the piezoelectric pillars 400 can be manufactured to have a smaller size than conventional ones, thereby enabling a more precise recognition of the three-dimensional pattern of a fingerprint. Alternatively, the three-dimensional shape recognition device using ultrasonic waves may be a device for measuring the three-dimensional shape of the organs and tissues in a human body. In addition, the three-dimensional shape recognition device using ultrasonic waves may be a device for measuring the shape of a human face.

Alternatively, besides a ultrasonic sensor, the electronic device including the piezoelectric element according to the preferred embodiment of the present invention may be any other electronic device using piezoelectric properties, such as a pressure sensor, a knocking sensor, a piezoelectric actuator, a piezoelectric energy harvesting device, a piezoelectric transformer, or a piezoelectric power generating mat.

Although the preferred embodiments of the present invention have been described above, those skilled in the art will appreciate that various modifications and changes are possible without departing from the spirit and scope of the invention as defined in the claims.

What is claimed is:

1. A method of manufacturing a piezoelectric element, the method comprising:
charging a piezoelectric material into at least one filling hole formed in a mold; and
sintering the piezoelectric material by heating only the piezoelectric material provided in the filling hole to a sintering temperature of the piezoelectric material.

2. The method of claim 1, wherein the sintering is performed in a manner that the mold is not heated to the sintering temperature and only the piezoelectric material is heated to the sintering temperature.

3. The method of claim 2, wherein the sintering is performed in a manner to heat only the piezoelectric material to the sintering temperature through a rapid thermal process.

4. The method of claim 2, wherein the sintering is performed in a manner to heat only the piezoelectric material to the sintering temperature through a high frequency heating process.

5. The method of claim 2, wherein the sintering is performed in a manner to heat only the piezoelectric material to the sintering temperature through a laser heating process.

6. The method of claim 1, wherein the sintering is a rapid thermal process by which a density of an end of the sintered piezoelectric material provided in the filling hole is higher than a density of the other portion of the sintered piezoelectric material.

7. A method of manufacturing a piezoelectric element, the method comprising:
preparing an anodic oxide film;
forming at least one filling hole extending through the anodic oxide film from an upper surface to a lower surface of the anodic oxide film, the filling hole being independent of pores formed in the anodic oxide film during the preparing of the anodic oxide film; and
forming a piezoelectric pillar by filling the filling hole with a piezoelectric material,
wherein the forming of the piezoelectric pillar includes a process of selectively heating only the piezoelectric material provided in the filling hole to a sintering temperature so that the piezoelectric material is sintered.

8. A piezoelectric element comprising:
an anodic oxide film; and
a piezoelectric pillar made from a piezoelectric material that is provided in the anodic oxide film and heated to a sintering temperature to be sintered.

9. An electronic device equipped with a piezoelectric element, the device comprising:
an anodic oxide film;
a piezoelectric pillar made from a piezoelectric material that is provided in the anodic oxide film and heated to a sintering temperature to be sintered;
a first electrode formed on an upper surface of the anodic oxide film; and
a second electrode formed on a lower surface of the anodic oxide film.
